(19) United States
(12) Patent Application Publication
(10) Pub. No.: US 2026/0291488 A1
(43) Pub. Date: Sep. 24, 2026

(54) SIGNAL TRANSMISSION DEVICE AND GATE DRIVE DEVICE

(71) Applicants: KABUSHIKI KAISHA TOSHIBA, Kawasaki-shi (JP); TOSHIBA ELECTRONIC DEVICES & STORAGE CORPORATION, Kawasaki-shi (JP)

(72) Inventors: Reiji TAGOMORI, Yokohama Kanagawa (JP); Shoji OOTAKA, Yokohama Kanagawa (JP); Yoshiharu NITO, Yokohama Kanagawa (JP); Satoru OSHITA, Hadano Kanagawa (JP)

(73) Assignees: KABUSHIKI KAISHA TOSHIBA, Kawasaki-shi (JP); TOSHIBA ELECTRONIC DEVICES & STORAGE CORPORATION, Kawasaki-shi (JP)

(21) Appl. No.: 19/367,936

(22) Filed: Oct. 24, 2025

(30) Foreign Application Priority Data
Mar. 21, 2025 (JP) 2025-047049

(51) Int. Cl. H03K 17/16

(52) U.S. Cl. CPC H03K 17/162; H03K 2217/0009; H03K 2217/0027

(57) ABSTRACT

According to the present embodiment, a detector includes one or more first identifiers, one or more second identifiers, a first encoder, and a second encoder. The first identifiers are each configured to compare the terminal voltage with a positive predetermined voltage. The second identifiers are each configured to compare the terminal voltage with a negative predetermined voltage. The first encoder is configured to perform encoding of information related to a slew rate of the terminal voltage on the basis of a comparison result of the first identifiers. The second encoder is configured to perform encoding of information related to a slew rate of the terminal voltage on the basis of a comparison result of the second identifiers.

### CROSS-REFERENCE TO RELATED APPLICATIONS

This application is based upon and claims the benefit of priority from the prior Japanese Patent Application No. 2025-047049, filed on Mar. 21, 2025 the entire contents of which are incorporated herein by reference.

### FIELD

The embodiments of the present invention relate to a signal transmission device and a gate drive device.

### BACKGROUND

A signal transmission device that performs inter-isolation transmission of a signal using an isolator is known. However, there is a risk that an error occurs in the inter-isolation transmission due to noise between insulating grounds.

### BRIEF DESCRIPTION OF THE DRAWINGS

FIG. 1 is a block diagram illustrating a signal transmission device according to the present embodiment;

FIG. 2 is a diagram illustrating an equivalent circuit example of an AC coupler illustrated in FIG. 1;

FIG. 3 is a diagram illustrating another equivalent circuit example of the AC coupler;

FIG. 4 is a diagram illustrating an equivalent circuit example of a signal transmitter;

FIG. 5 is a diagram illustrating a voltage of CMT noise and a voltage amplitude between grounds;

FIG. 6 is a block diagram illustrating an example of an output signal from a CMT detector according to the present embodiment;

FIG. 7 is a block diagram illustrating another example of an output signal from the CMT detector according to the present embodiment;

FIG. 8 is a block diagram illustrating a configuration example of the CMT detector according to the present embodiment;

FIG. 9 is a flowchart illustrating a processing example of a direction selector;

FIG. 10 is a diagram illustrating an amplifier output when CMT noise is input;

FIG. 11 is a diagram illustrating another amplifier output when CMT noise is input;

FIG. 12 is a timing chart illustrating a response example when CMT noise at a positive slew rate is applied;

FIG. 13 is a timing chart illustrating a response example when CMT noise at a negative slew rate is applied;

FIG. 14 is a circuit diagram illustrating a more detailed configuration example of the CMT detector;

FIG. 15 is a diagram illustrating a response example when CMT noise at a positive slew rate is applied;

FIG. 16 is a diagram illustrating a response example when CMT noise at a negative slew rate is applied;

FIG. 17 is a diagram illustrating a logic circuit example of the direction selector;

FIG. 18 is a truth table of a positive signal and a negative signal;

FIG. 19 is a timing chart in a case where CMT noise having a positive inclination is applied and a waveform distortion occurs;

FIG. 20 is a diagram illustrating a configuration example of an isolation amplifier as the signal transmission device according to the first embodiment;

FIG. 21 is a diagram illustrating another configuration example of the isolation amplifier as the signal transmission device according to the first embodiment;

FIG. 22 is a diagram illustrating a configuration example as a gate drive device;

FIG. 23 is a diagram illustrating an example of a transient response of a drain voltage;

FIG. 24 is a block diagram illustrating a configuration on a power high side; and

FIG. 25 is a timing chart illustrating a processing example on the power high side.

### DETAILED DESCRIPTION

According to the present embodiment, a signal transmission device includes a primary circuit, an AC coupler, a secondary circuit, and a detector. The AC coupler is configured to transmit a transmission signal received from the primary circuit. The secondary circuit is configured to receive the transmission signal transmitted from the AC coupler. The detector is configured to output a detection signal related to a noise level at the time of transmission of the transmission signal according to fluctuations of a terminal voltage based on a current flowing in at least either a first reference potential terminal of the primary circuit isolated by the AC coupler or a second reference potential terminal of the secondary circuit. The detector includes one or more first identifiers, one or more second identifiers, a first encoder, and a second encoder. The first identifiers are each configured to compare the terminal voltage with a positive predetermined voltage. The second identifiers are each configured to compare the terminal voltage with a negative predetermined voltage. The first encoder is configured to perform encoding of information related to a slew rate of the terminal voltage on the basis of a comparison result of the first identifiers. The second encoder is configured to perform encoding of information related to a slew rate of the terminal voltage on the basis of a comparison result of the second identifiers.

Embodiments of the present invention will now be explained below with reference to the drawings. In the following explanations, the same members, similar members, and the like are denoted by like reference signs and, as for members and the like having been described once, redundant explanations thereof are omitted as appropriate.

### First Embodiment

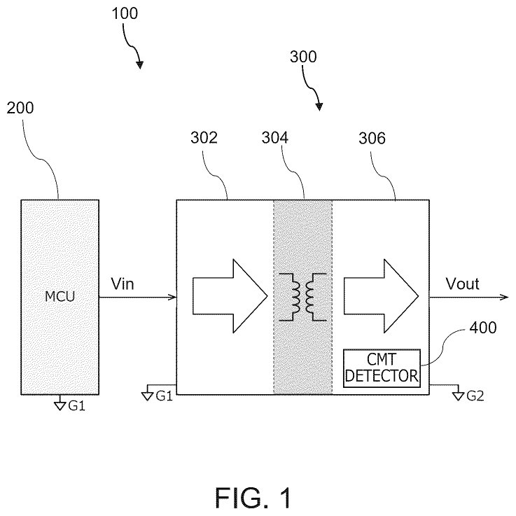

FIG. 1 is a block diagram illustrating a signal transmission device 100 according to the present embodiment. As illustrated in FIG. 1, the signal transmission device 100 is an example of an isolator using a transformer. The signal transmission device 100 includes a controller 200, a signal transmitter 300, and a CMT detector 400.

The controller 200 is, for example, a microprocessor (MPU: Micro Processing Unit) and outputs a signal Vin to the signal transmitter 300. The signal transmitter 300 includes a primary chip 302, an AC coupler 304, and a secondary chip 306.

The primary chip 302 is, for example, a transmitting circuit. The primary chip 302 transmits the signal Vin in an isolated manner to the secondary chip 306 via the AC coupler 304. The primary chip 302 according to the present embodiment corresponds to a primary circuit.

The AC coupler 304 transmits the signal Vin generated by the primary chip 302 to the secondary chip 306. This AC coupler 304 is, for example, a transformer. A primary ground G1 of the primary chip 302 and a secondary ground G2 of the secondary chip 306 are galvanically isolated by the AC coupler 304. While being a transformer in the present embodiment, the AC coupler 304 is not limited thereto. For example, the AC coupler 304 may be an isolated microcapacitor or an optical isolator that is galvanically isolated.

The secondary chip 306 is, for example, a receiving circuit. The secondary chip 306 outputs a signal received via the AC coupler 304 as a signal Vout. The secondary chip 306 according to the present embodiment corresponds to a secondary circuit.

There is a case where rapid electrical fluctuations occur between the primary ground G1 and the secondary ground G2 that are isolated. These electrical fluctuations are also referred to as “common mode transient (CMT) noise”. Hereinafter, the primary ground G1 is also referred to as “ground G1” and the secondary ground G2 is also referred to as “ground G2”.

In the signal transmission device 100, an error may occur in inter-isolation data transmission due to large CMT noise between the ground G1 and the ground G2. Conventionally, CMT noise is not detected at the time of data transmission. Therefore, even when an error occurs in data transmission, the error is not detected. Accordingly, there is a case where reliability of data transmission is decreased.

The CMT detector 400 detects occurrence of CMT noise and detects the level of the noise. This enables the CMT detector 400 to determine whether the level of the CMT noise is above an acceptable value at which a transmission error is highly likely to occur. The CMT detector 400 according to the present embodiment corresponds to a detector.

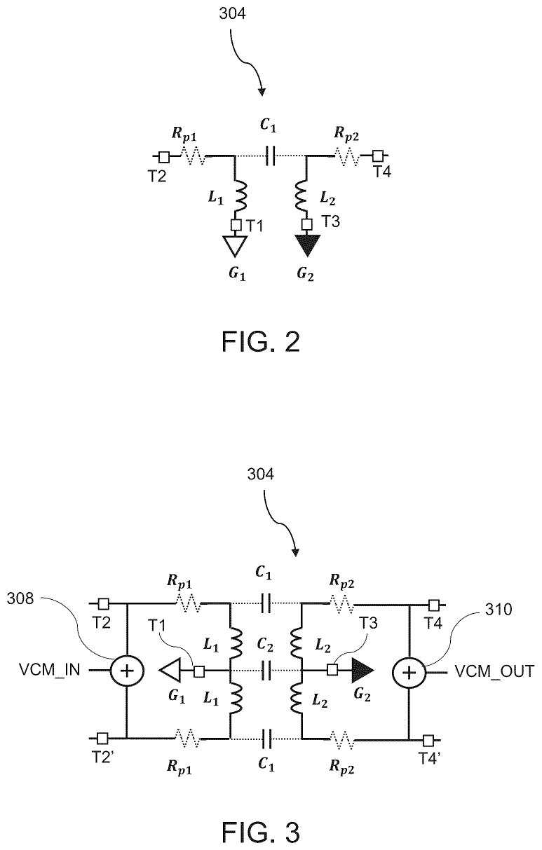

FIG. 2 is a diagram illustrating an equivalent circuit example of the AC coupler 304 illustrated in FIG. 1. FIG. 2 illustrates an example where the AC coupler 304 has a transformer. That is, a transformer is coupled in an isolated manner between terminals T1, T2 of the primary chip 302 and terminals T3, T4 of the secondary chip 306. In this way, each of the terminals T1 and T3 is connected to a ground being a reference potential.

A primary ground (GND) is denoted by G1, a secondary GND is denoted by G2, a primary inductor of the transformer is denoted by L1, a secondary inductor thereof is denoted by L2, a primary parasitic resistor is denoted by Rp1, a secondary parasitic resistor is denoted by Rp2, and a parasitic capacitor between the inductors is denoted by C1. To simplify descriptions, an equivalent circuit in an example where the parasitic capacitor of an inductor is configured at an inductor end is illustrated. As described above, the transformer causes the inductors having a potential of the first reference potential terminal T1 and a potential of the second reference potential terminal T3 as references to be close to each other to transmit a signal from the primary chip 302 to the secondary chip 306 or from the secondary chip 306 to the primary chip 302.

The CMT detector 400 detects CMT noise. That is, the CMT detector 400 outputs a signal corresponding to fluctuations of a voltage between the first reference potential terminal T1 of the primary chip 302 and the second reference potential terminal T3 of the secondary chip 306, which are isolated by the AC coupler 304. Details of the CMT detector 400 will be described later.

FIG. 3 is a diagram illustrating another equivalent circuit example of the AC coupler 304. In FIG. 3, an equivalent circuit example in which a transformer with a center tap is used as the AC coupler 304 is illustrated. That is, this is an example of a transformer in which the center tap is connected to the primary ground G1 via the terminal T1 and to the secondary ground G2 via the terminal T3. For example, an on-off keying (OOK) differential signal output from a drive circuit (not illustrated) is input to terminals T2 and T2′ and is output to a wave detection circuit (not illustrated) from terminals T4 and T4′ through the AC coupler 304.

As illustrated in FIGS. 2 and 3, when GND potentials of the grounds G1 and G2 fluctuate, a common-mode signal is generated and a current flows via the parasitic capacitor C1. This becomes CMT noise.

In the case illustrated in FIG. 3, the signals at the terminals T2 and T2′ are added to detect a common-mode signal at the terminals T2 and T2′. Similarly, the signals at the terminals T4 and T4′ are added to detect a common-mode signal at the terminals T4 and T4′. While a transformer is used as an example in the following descriptions, the embodiment is not limited thereto.

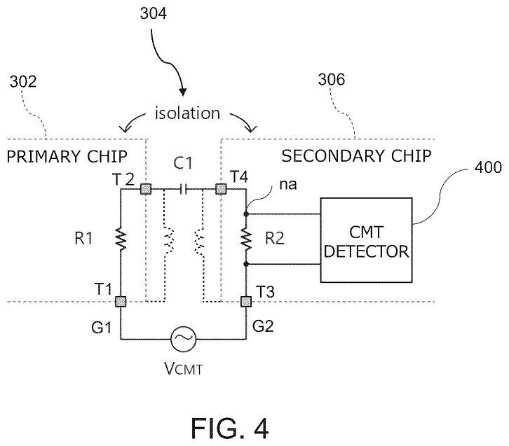

FIG. 4 is a diagram illustrating an equivalent circuit example of the signal transmitter 300. In the primary chip 302, the primary ground G1 is connected to the first terminal T1. A resistor R1 is connected between the first terminal T1 and the second terminal T2. In the secondary chip 306, the secondary ground G2 is connected to the third terminal T3. A resistor R2 is connected between the third terminal T3 and the fourth terminal T4.

The CMT detector 400 is connected to both ends of the resistor R2. A capacitor C1 represents a capacitor between isolators that are parasitic in an isolation transformer indicated by broken lines. That is, the capacitor C1 corresponds to the parasitic capacitor C1 (see FIGS. 2 and 3). Since CMT noise is a steep signal and the impedances of the inductors L1 and L2 (see FIGS. 2 and 3) become high, the inductors L1 and L2 are ignored in descriptions to simplify the descriptions.

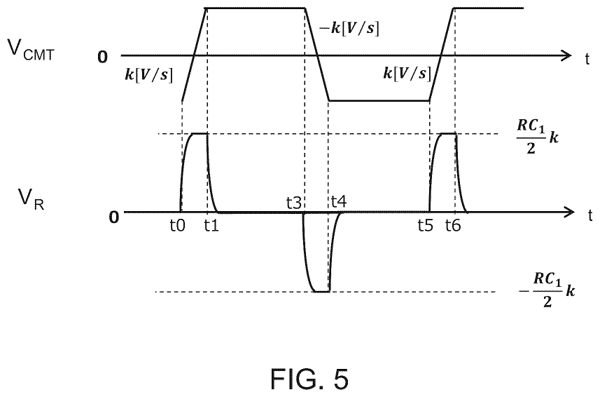

FIG. 5 is a diagram illustrating a voltage V_{CMT} of CMT noise based on the ground G2 and a voltage amplitude V_{R} at a node na of the secondary chip based on the ground G2. The horizontal axis represents the time and the vertical axis represents the voltage V_{CMT} of CMT noise and the voltage amplitude V_{R} at the node na. In FIG. 5, an example in which the voltage V_{CMT} at a slew rate k is periodically applied between the grounds G1 and G2 is described. Hereinafter, CMT noise is also represented simply by CMT and the voltage V_{CMT} of CMT noise is also represented by V_{CMT}.

When the voltage V_{CMT} increases from a negative value to a positive value in periods of times from t0 to t1 and from t5 to t6 as illustrated in FIG. 5, the voltage amplitude V_{R} at a point of the node na is represented by an expression (1).

$$\begin{matrix}[ Expression 1 ] & \\ {v}_{R} = \frac{{kRC}_{1}}{2} \cdot ( 1 - {e}^{- \frac{t}{{RC}_{1}}} ) & ( 1 )\end{matrix}$$

As described above, R1 and R2 denote resistors, R=R1+R2, and C1 denotes the parasitic capacitor of the transformer. The slew rate k indicates a voltage that changes per unit time of the voltage V_{CMT}.

When t>>RC₁, an expression (2) is obtained. That is, when a transient response represented by the expression (1) is in a steady state, the voltage amplitude V_{R} represented by the expression (2) is obtained.

$$\begin{matrix}[ Expression 2 ] & \\ {v}_{R} = \frac{{RC}_{1}}{2} \cdot k & ( 2 )\end{matrix}$$

On the other hand, when the CMT noise decreases from a positive value to a negative value in a period of times from t3 to t4, the voltage amplitude V_{R} at the point of the node na is represented by an expression (3).

$$\begin{matrix}[ Expression 3 ] & \\ {v}_{R} = - \frac{{kRC}_{1}}{2} \cdot ( 1 - {e}^{- \frac{t}{{RC}_{1}}} ) & ( 3 )\end{matrix}$$

When t>>RC₁, an expression (4) is obtained.

$$\begin{matrix}[ Expression 4 ] & \\ {v}_{R} = - \frac{{RC}_{1}}{2} \cdot k & ( 4 )\end{matrix}$$

As described above, the voltage amplitude V_{R} at the point of the node na becomes pulses with an amplitude depending on the slew rate k.

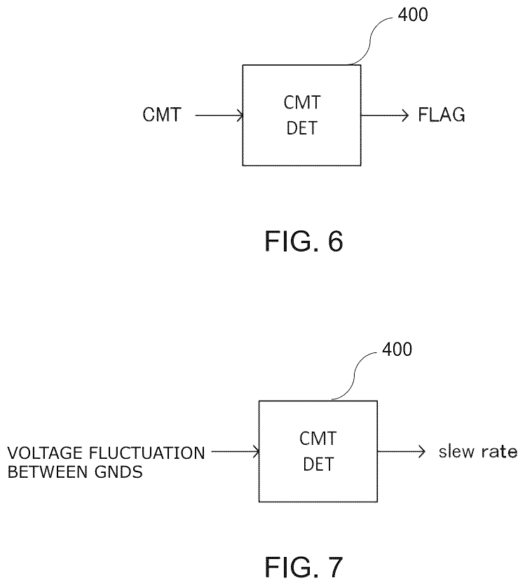

FIG. 6 is a block diagram illustrating an example of an output signal from the CMT detector 400 according to the present embodiment. When CMT noise occurs, the CMT detector 400 detects the magnitude of the CMT noise and outputs a flag signal FLAG when the magnitude is equal to or greater than a predetermined level. A processor and the like that have received the flag signal FLAG at the subsequent stage are enabled to perform processing in response to the flag signal FLAG. In this way, since whether a transmission error has occurred cannot be determined on the reception side, the reliability of data can be determined based on this flag signal FLAG.

FIG. 7 is a block diagram illustrating another example of an output signal from the CMT detector 400 according to the present embodiment. When CMT noise occurs, the CMT detector 400 outputs a slew rate signal having information about a value related to a slew rate based on the magnitude of the CMT noise.

As described above, CMT noise corresponds to rapid potential fluctuations of the primary or secondary GND and detection of the amplitude of CMT noise is equivalent to detection of the slew rate k of CMT as indicated by the expressions (2) and (4).

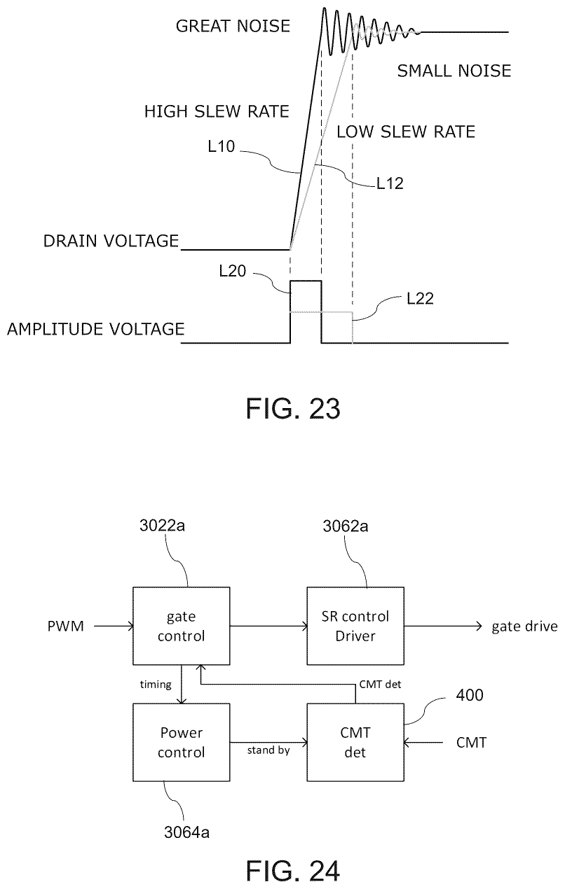

For example, in a case where the CMT detector 400 is used in a gate driver or the like, radio emission due to common-mode potential fluctuations needs to be equal to or lower than a predetermined level so as not to affect other measuring devices and the like. The radio emission correlates with the slew rate, and it is only necessary to lower the slew rate to decrease the radio emission. When the slew rate is lowered, the amplitude of the CMT noise is decreased (see FIG. 23 described later).

Therefore, when the slew rate can be detected by observation of the CMT noise amplitude and when the slew rate is equal to or higher than a specified value, the radio emission is highly likely to be equal to or higher than a specified level. Accordingly, it becomes possible to notify the gate driver to lower the slew rate of the CMT noise.

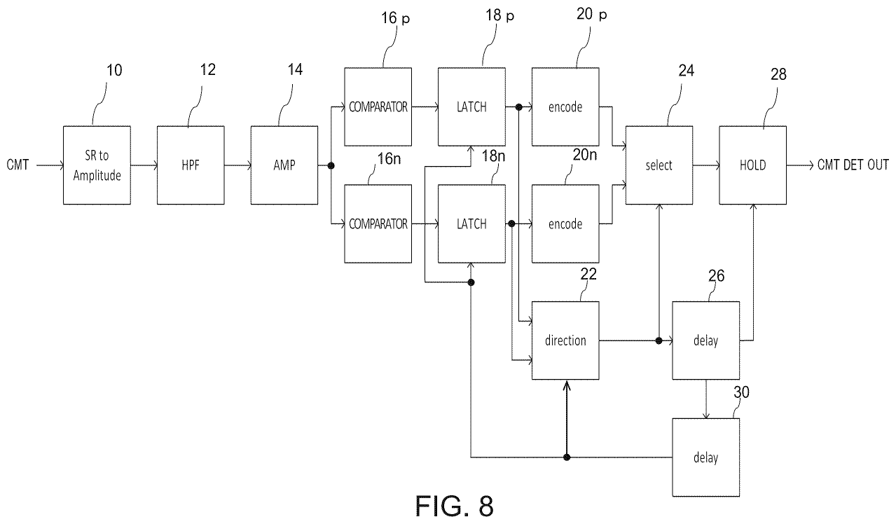

FIG. 8 is a block diagram illustrating a configuration example of the CMT detector 400 according to the present embodiment. The CMT detector 400 includes a voltage converter 10, a noise suppressor 12, an amplifier 14, a positive-side comparator 16p, a negative-side comparator 16n, a positive-side storage 18p, a negative-side storage 18n, a positive-side encoder 20p, a negative-side encoder 20n, a direction selector 22, a selector 24, a first delay circuit part 26, a holder 28, and a second delay circuit part 30.

The voltage converter (SR to Amplitude) 10 is a block that converts CMT noise into a voltage amplitude. The voltage converter 10 corresponds to, for example, the resistor R2 (see FIG. 4) to which the CMT detector 400 is connected or the resistor R1 (see FIG. 4).

The noise suppressor (HPF) 12 is, for example, a high-pass filter and suppresses low-frequency noise. It is possible that the noise suppressor (HPF) 12 is not included when low-frequency noise is small.

The amplifier (AMP) 14 is an amplifier stage. The amplifier 14 sets a gain according to CMT noise to be detected.

The positive-side comparator (COMPARATOR) 16p is a comparator used when CMT noise has a positive slew rate (see FIG. 5). The positive-side comparator 16p compares a CMT noise level with positive levels at plural stages.

The negative-side comparator (COMPARATOR) 16n has substantially the same configuration as that of the positive-side comparator 16p. The negative-side comparator 16n is a comparator used when CMT noise has a negative slew rate (see FIG. 5). The negative-side comparator 16n compares a CMT noise level with negative levels at plural stages. The positive-side comparator 16p and the negative-side comparator 16n according to the present embodiment correspond to identifiers.

As described above, the polarity of the output from the voltage converter 10 changes depending on the polarity of the slew rate. Therefore, the positive-side comparator 16p corresponding to the positive amplitude polarity and the negative-side comparator 16n corresponding to the negative amplitude polarity are used.

The positive-side storage (LATCH) 18p is a plurality of latch circuits corresponding to the positive-side comparator 16p. The positive-side storage 18p stores therein comparison results of the positive-side comparator 16p. A timing when the latch circuits are latch-cleared will be described later.

The negative-side storage (LATCH) 18n is a plurality of latch circuits corresponding to the negative-side comparator 16n. The negative-side storage 18n stores therein comparison results of the negative-side comparator 16n. A timing when the latch circuits are latch-cleared will be described later.

The positive-side encoder (encode) 20p encodes the storage results in the positive-side storage 18p. Similarly, the negative-side encoder (encode) 20n encodes the storage results in the negative-side storage 18n. The positive-side encoder 20p according to the present embodiment corresponds to a first encoder and the negative-side encoder 20n corresponds to a second encoder. The positive-side encoder 20p and the negative-side encoder 20n according to the present embodiment correspond to an encoder.

The direction selector (direct) 22 determines whether CMT noise is a positive pulse or a negative pulse. That is, the direction selector 22 outputs a selection signal that selects whether the slew rate (see FIG. 5) of CMT noise is positive or negative.

The selector 24 selects an encoding result of the positive-side encoder 20p or the negative-side encoder 20n in accordance with the selection signal from the direction selector 22 and outputs the selected encoding result to the holder 28.

The first delay circuit part 26 adjusts an output timing of the selector 24 and a signal load timing of the holder 28. The first delay circuit part 26 is, for example, a buffer and delays the output signal from the direction selector 22 to output the delayed signal to the holder 28.

The holder 28 holds the encoding result selected by the selector 24. The holder 28 holds the encoding result selected by the selector 24 at a timing through the first delay circuit part 26. The transient response of CMT noise converges to be substantially constant due to these two block delays.

The second delay circuit part 30 delays the output signal from the first delay circuit part 26 to reset the positive-side storage 18p and the negative-side storage 18n. That is, the positive-side storage 18p and the negative-side storage 18n latch-clear the latch circuits at a timing when a positive/negative determination signal from the direction selector 22 is input. In this way, the positive-side storage 18p and the negative-side storage 18n are latch-cleared according to a transmission delay through the circuit parts 24, 26, and 30 that produce three delays, and are brought to a state of waiting for a transient signal of next CMT noise.

It is difficult for a circuit that provides a ground GND with positive power to detect or process a signal equal to or lower than the ground GND. Therefore, processing of the noise suppressor 12 and the following components is performed using differential circuit and a positive/negative signal is processed by switching of a differential signal.

The noise suppressor 12 and the amplifier 14 may be components provided as required. For example, the voltage amplitude V_{R} to be detected is proportional to the slew rate k as indicated by the expressions (2) and (4). Therefore, in a case where only CMT noise at a high slew rate k is to be detected, signal processing may be performed without amplification processing of the amplifier 14.

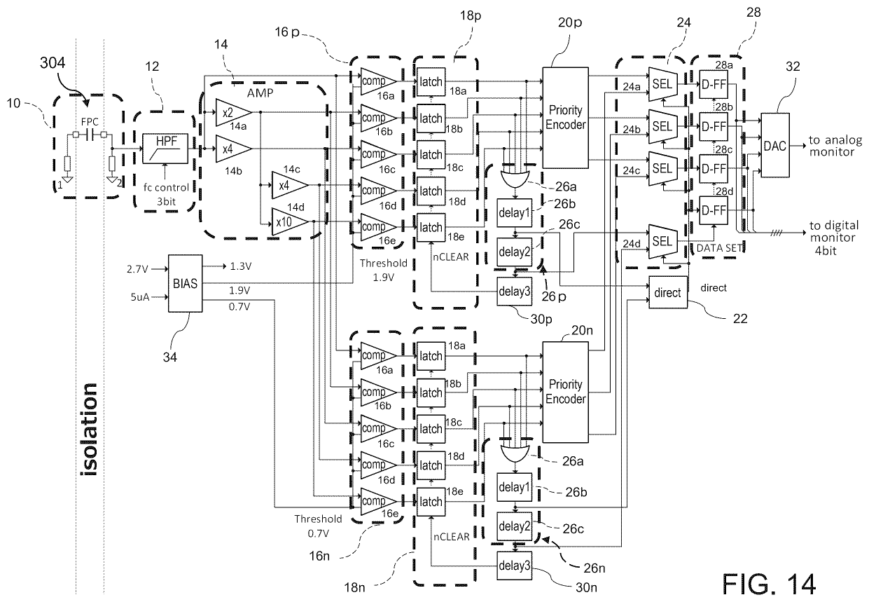

Furthermore, the number of comparators required in each of the positive-side comparator 16p and the negative-side comparator 16n depends on the resolution of the slew rate to be detected (see FIG. 14 described later for details). For example, when slew rate zones to be detected are four, three comparators (comp) are required.

As described above, one of characteristics of the CMT detector 400 according to the present embodiment is operating with CMT noise itself as a trigger. That is, when CMT noise is input, the states of the positive-side comparator 16p and the negative-side comparator 16n change. This change is input to the positive-side storage 18p, the negative-side storage 18n, the direction selector 22, and the first delay circuit part 26, and a predetermined result is held by the holder 28. A predetermined time after, the positive-side storage 18p and the negative-side storage 18n are cleared and enter the next CMT noise detection period. The CMT detector 400 is also characterized in including the direction selector 22 that determines the polarity of CMT noise to switch the route according to the polarity. Accordingly, the processing can be divided to processing according to the polarity and the circuit is simplified, so that the speed can be further increased.

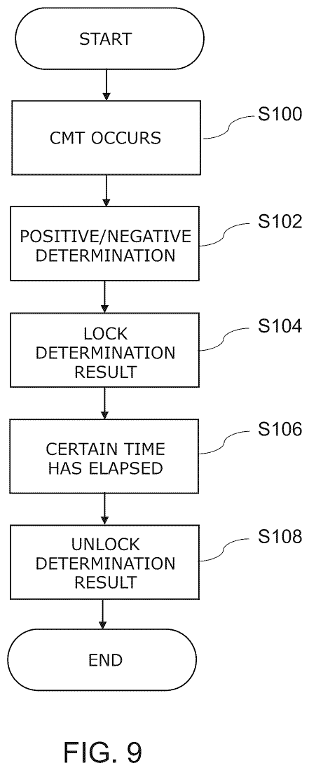

FIG. 9 is a flowchart illustrating a processing example of the direction selector 22. As illustrated in FIG. 9, output results of the positive-side comparator 16p and the negative-side comparator 16n are input to the direction selector 22 (Step S100).

Next, the direction selector 22 determines whether CMT noise is positive or negative using the output results of the positive-side comparator 16p and the negative-side comparator 16n (Step S102). The positive-side comparator 16p responds when the CMT noise is positive, and the negative-side comparator 16n responds when the CMT noise is negative. Accordingly, the direction selector 22 determines whether the CMT noise is positive or negative using stored information in the positive-side storage 18p and the negative-side storage 18n after reset.

Subsequently, the direction selector 22 locks and holds the determination result for a certain period. Accordingly, the direction selector 22 locks and outputs a signal including information indicating whether the CMT noise is positive or negative during the certain period to prevent the determination result from changing (Step S104).

Next, after a certain time has elapsed (Step S106), the direction selector 22 unlocks the determination result (Step S108) and prepares for CMT noise occurring next. Unlocking can be performed using a signal from the second delay circuit part 30 (see FIG. 8). The unlocking of the determination result for the certain period is to prevent erroneous determination due to a distortion cause occurring in an amplifier output.

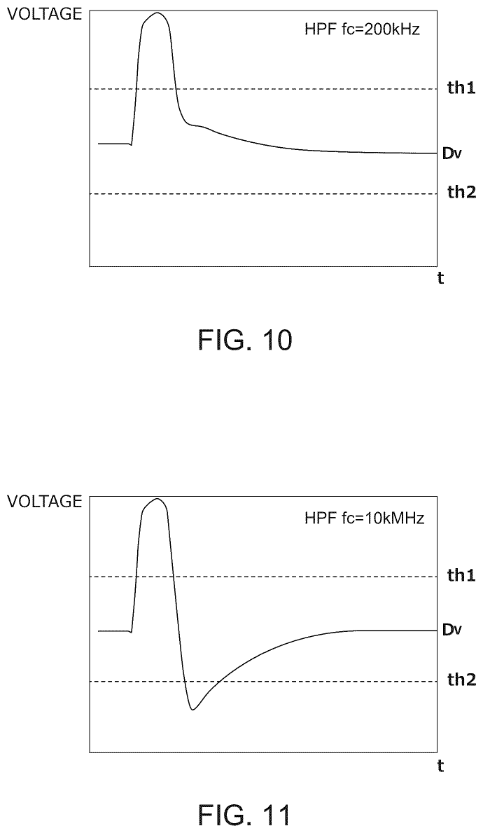

A distortion cause occurring in an amplifier output is described with reference to FIGS. 10 and 11. FIG. 10 is a diagram illustrating an amplifier output when CMT noise is input. FIG. 11 is a diagram illustrating another amplifier output when CMT noise is input. The horizontal axis represents the time and the vertical axis represents the voltage. FIG. 10 indicates an output result when the cutoff (fc) frequency of the noise suppressor 12 is 200 kHz and FIG. 11 indicates an output result when the cutoff (fc) frequency of the noise suppressor 12 is 10 MHz.

Thresholds th1 and th2 are an example of threshold voltages of the positive-side comparator 16p and the negative-side comparator 16n. When an output voltage from the noise suppressor 12 becomes equal to or higher than the threshold th1, the positive-side comparator 16p on the positive side transitions from L to H. Meanwhile, when the output voltage becomes equal to or lower than the threshold th2, the negative-side comparator 16n transitions from L to H.

In the case where the cutoff frequency is 200 kHz, when CMT noise is applied, the output voltage exceeds the threshold th1 on the positive side and an input of CMT noise at a positive slew rate is detected. After the application of the CMT noise, the output voltage returns to an original DC voltage Dv (for example, 1.2 V). Meanwhile, in the case where the HPF cutoff frequency is 10 MHz, the output voltage is in substantially the same state as that in the case of 200 kHz until the output voltage exceeds the threshold th1 on the positive side with respect to the DC voltage Dv. Meanwhile, the output voltage exceeds the threshold th2 on the negative side after the end of the CMT noise because the bandwidth of the cutoff frequency is wider. Accordingly, the direction selector 22 erroneously determines that a negative slew rate (−k) is input. To prevent this, the direction selector 22 has a function to lock determination for a certain period after determining that the voltage has once exceeded a threshold.

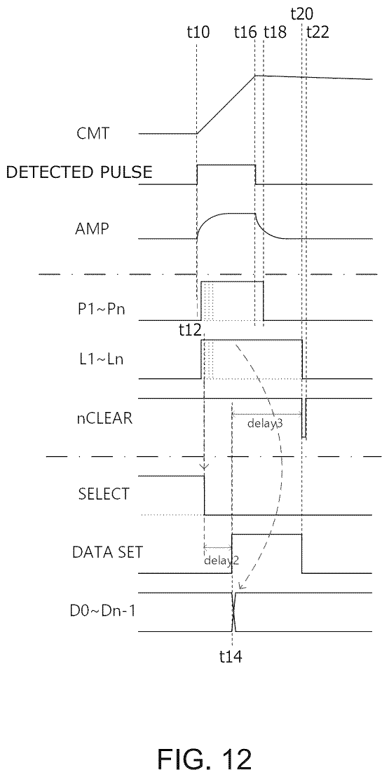

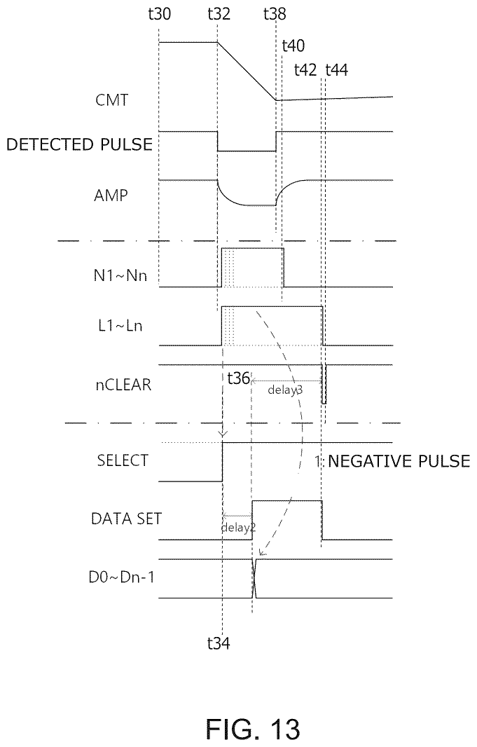

A timing chart illustrating a processing example of the CMT detector 400 according to the present embodiment is described using FIGS. 12 and 13 while referring to FIG. 8. FIG. 12 is a timing chart illustrating a response example when CMT noise at a positive slew rate is applied. CMT noise input to the voltage converter 10, a detected pulse (PULSE) input to the noise suppressor 12, an amplified pulse (AMP) output from the amplifier 14, output values (P1 to Pn) of the positive-side comparator 16p, stored values (L1 to Ln) in the positive-side storage 18p, an output signal (nCLEAR) of the second delay circuit part 30, an output signal (SELECT) of the direction selector 22, an output signal (DATA SET) of the first delay circuit part 26, and output signals (DO to Dn−1) of the holder 28 are illustrated in this order from the top.

A response at a time of application of CMT noise at a positive slew rate is described first. At a time t10, CMT noise is input to the voltage converter 10 and the voltage converter 10 starts an output corresponding to a time derivative. The amplifier 14 starts outputting the time derivative of the CMT noise as a rectangular pulse waveform (see FIG. 5).

The positive-side comparator 16p compares the voltage amplitude V_{R} of the rectangular pulse waveform with n threshold voltages P1 to Pn.

At a time t12, the voltage amplitude V_{R} of the rectangular pulse waveform exceeds any of the n threshold voltages P1 to Pn. Accordingly, the positive-side comparator 16p transitions from L to H in response to the threshold voltages P1 to Pn exceeded by the voltage amplitude V_{R}. For example, when the voltage amplitude V_{R} is P4, the output values P1, P2, P3, and P4 transition from L to H and the output value P5 and the subsequent values are maintained at L. This indicates that the voltage amplitude V_{R} is between P4 and P5.

The output values of the positive-side comparator 16p are input to the positive-side storage 18p at the subsequent stage. Information indicating L or H is set as each of the stored values (L1 to Ln) in the corresponding latches. While not indispensable, the latches can prevent a determination result at a time of logic determination from changing when the detected pulse width is short.

Meanwhile, the stored values (L1 to Ln) in the latches of the negative-side storage 18n at the subsequent stage are all L. Accordingly, a signal for selecting the positive-side storage 18p that has output the value H is output as the output signal (SELECT) of the direction selector 22. In this case, the output signal (SELECT) of the direction selector 22 transitions from H to L.

The positive-side encoder 20p generates codes corresponding to the stored values (L1 to Ln) in the latches of the positive-side storage 18p.

The selector 24 selects a code of the positive-side encoder 20p in accordance with the output signal (SELECT) of the direction selector 22.

When a delay time delay2 of the first delay circuit part 26 has elapsed at a time t14, the holder 28 holds codes DO to Dn−1 indicating the positive voltage amplitude V_{R} of the positive-side encoder 20p and outputs the codes to the subsequent stage.

When the CMT noise becomes a constant value at a time t16, the output of the detected pulse (PULSE) of the voltage converter 10 becomes a low level. At a time t18, the output of the positive-side comparator 16p becomes L.

When a delay time delay3 of the second delay circuit part 30 has elapsed in addition to the delay time delay2 at a time t20, the output signal (nCLEAR) of the second delay circuit part 30 transitions from a high level to a low level and is input to the positive-side storage 18p. Accordingly, the stored values (L1 to Ln) in the latches of the positive-side storage 18p are latch-reset and the output signal of the first delay circuit part 26 also becomes L. At a time t22, the output signal (nCLEAR) of the second delay circuit part 30 transitions from the low level to the high level and the next processing is started.

FIG. 13 is a timing chart illustrating a response example when CMT noise at a negative slew rate is applied. CMT noise input to the voltage converter 10, a detected pulse (PULSE) input to the noise suppressor 12, an amplified pulse (AMP) output from the amplifier 14, output values (N1 to Nn) of the negative-side comparator 16n, stored values (L1 to Ln) in the negative-side storage 18n, the output signal (nCLEAR) of the second delay circuit part 30, the output signal (SELECT) of the direction selector 22, the output signal (DATA SET) of the first delay circuit part 26, and the output signals (DO to Dn−1) of the holder 28 are illustrated in this order from the top.

In FIG. 13, differences of the response example at the time of application of CMT noise at a negative slew rate from the response example in FIG. 12 are described.

An input of the CMT noise to the voltage converter 10 is close to the end at a time t30, and the voltage converter 10 starts an output corresponding to a time derivative at a time t32. The amplifier 14 starts outputting the time derivative of the CMT noise as a negative rectangular pulse waveform (see FIG. 5).

The negative-side comparator 16n compares a voltage amplitude −V_{R} of the negative rectangular pulse waveform with n threshold voltages N1 to Nn.

At a time t34, the voltage amplitude −V_{R} of the negative rectangular pulse waveform exceeds any of the n threshold voltages N1 to Nn. Accordingly, the negative-side comparator 16n transitions from L to H in response to the threshold voltages N1 to Nn exceeded by the amplitude voltage −V_{R}. For example, when the voltage amplitude −V_{R} is N4, the output values N1, N2, N3, and N4 transition from L to H and the output value N5 and the subsequent values are maintained at L. This indicates that the voltage amplitude −V_{R} is between N4 and N5.

The output values of the negative-side comparator 16n are input to the negative-side storage 18n at the subsequent stage. Information indicating L or H is set as each of the stored values (L1 to Ln) in the corresponding latches. While not indispensable, the latches can prevent a determination result at a time of logic determination from changing when the detected pulse width is short.

Meanwhile, the stored values (L1 to Ln) in the latches of the positive-side storage 18p at the subsequent stage are all L. Accordingly, a signal for selecting the negative-side storage 18n that has output the value H is output as the output signal (SELECT) of the direction selector 22. In this case, the output signal (SELECT) of the direction selector 22 transitions from L to H.

The negative-side encoder 20n generates codes corresponding to the stored values (L1 to Ln) in the latches of the negative-side storage 18n. The selector 24 selects a code of the negative-side encoder 20n in accordance with the output signal (SELECT) of the direction selector 22.

When the delay time delay2 of the first delay circuit part 26 has elapsed at a time t36, the holder 28 holds codes DO to Dn−1 indicating the negative voltage amplitude −V_{R} of the negative-side encoder 20n and outputs the codes to the subsequent stage.

When the CMT noise becomes a constant value at a time t38, the output of the detected pulse (PULSE) of the voltage converter 10 becomes a high level. At a time t40, the output of the negative-side comparator 16n becomes L.

When the delay time delay3 of the second delay circuit part 30 has elapsed in addition to the delay time delay2 at a time t42, the output signal (nCLEAR) of the second delay circuit part 30 transitions from a high level to a low level and is input to the negative-side storage 18n. Accordingly, the stored values (N1 to Nn) in the latches of the negative-side storage 18n are latch-reset and the output signal of the first delay circuit part 26 also becomes L. At a time t44, the output signal (nCLEAR) of the second delay circuit part 30 transitions from the low level to the high level and the next processing is started.

FIG. 14 is a circuit diagram illustrating a more detailed configuration example of the CMT detector 400. As illustrated in FIG. 14, a digital-analog converter (DAC) 32 and a bias power supply 34 are further added.

The noise suppressor 12 is configured in such a manner that the cutoff (fc) frequency can be set by, for example, a 3-bit signal. The amplifier 14 includes a plurality of amplifiers 14a to 14d. Accordingly, the amplifier 14 can perform 2-fold, 4-fold, 8-fold, and 20-fold amplification. Substantially the same configurations on the positive side and the negative side are denoted by the same reference number and redundant descriptions are omitted in some cases.

The positive-side comparator 16p has identifiers 16a to 16e corresponding to the amplifiers 14a to 14d. The identifiers 16a to 16e compare whether the output value of the amplifier 14 is above one time, two times, four times, eight times, and twenty times as large as a reference threshold. The identifiers 16a to 16e output a high-level signal H when the output value is above the values, and output a low-level signal L when the output value is not above the values.

The positive-side storage 18p has latches 18a to 18e corresponding to the identifiers 16a to 16e of the positive-side comparator 16p, and stores therein the output values of the identifiers 16a to 16e. Similarly, the negative-side storage 18n has latches 18a to 18e corresponding to the identifiers 16a to 16e of the negative-side comparator 16n, and stores therein the output values of the identifiers 16a to 16e.

The positive-side encoder 20p encodes the values of the latches 18a to 18e of the positive-side storage 18p. Similarly, the negative-side encoder 20n encodes the values of the latches 18a to 18e of the negative-side storage 18n.

The first delay circuit part 26 is constituted of a delay circuit 26p on the positive side and a delay circuit 26n on the negative side. Each of the delay circuit 26p on the positive side and the delay circuit 26n on the negative side is constituted of an OR element 26a and two buffers 26b and 26c. An output of the buffer 26b at the first stage is input to the direction selector 22 and an output of the buffer 26c at the second stage is input to the selector 24.

The selector 24 includes a plurality of multiplexers 24a to 24c that receive signals from the positive-side encoder 20p and the negative-side encoder 20n, and a multiplexer 24d that receives output signals from the buffers at the second stage in the delay circuit 26p on the positive side and the delay circuit 26n on the negative side. Each of the multiplexers 24a to 24d selects a signal on the positive side or the negative side in accordance with the signal of the direction selector 22.

The holder 28 includes D-type flip-flops 28a to 28d. D-type flip-flops of the D-type flip-flops 28a to 28d store therein output values of the corresponding multiplexers 24a to 24d, respectively.

The digital-analog converter (DAC) 32 converts the values of the D-type flip-flops 28a to 28d of the holder 28 into a digital signal. The bias power supply 34 sets the reference threshold for each of the identifiers 16a to 16e of the positive-side comparator 16p and the identifiers 16a to 16e of the negative-side comparator 16n. With this configuration, the magnitude of the amplitude of CMT noise can be digitalized.

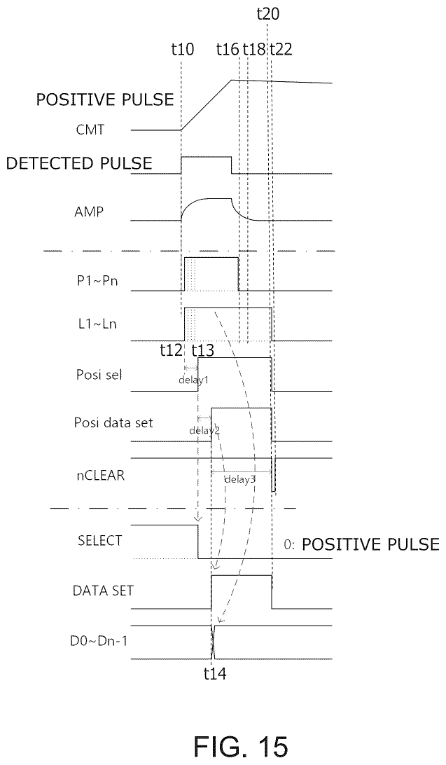

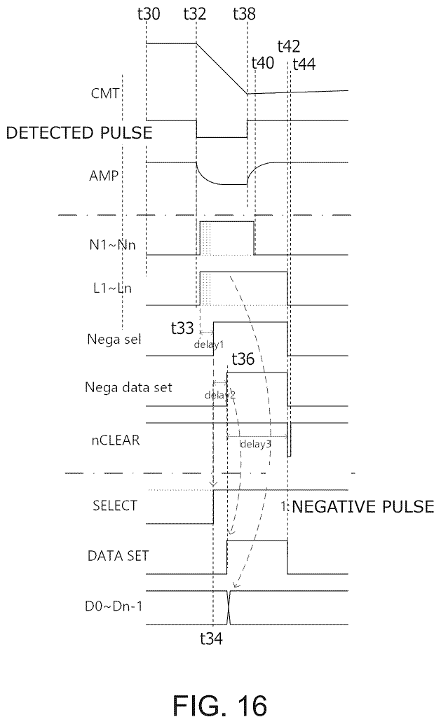

FIGS. 15 and 16 are timing charts illustrating processing examples of the CMT detector 400 illustrated in FIG. 14. FIG. 15 is a diagram illustrating a response example when CMT noise at a positive slew rate is applied. FIG. 16 is a diagram illustrating a response example when CMT noise at a negative slew rate is applied.

The processing is described with reference to FIG. 14. FIG. 15 is different from FIG. 12 in that an output signal Posi sel and an output signal Posi data set of the two buffers 26b and 26c in the delay circuit 26p on the positive side are added. That is, a high-level signal H is held in any of the latches 18a to 18e of the positive-side storage 18p at a time t12.

At a time t13 that is a delay time delay1 after the time t12, the buffer 26b outputs the output signal Posi sel to the direction selector 22. Accordingly, the direction selector 22 changes the selection signal SELECT from 1 to 0 to output the selection signal SELECT that selects a signal on the positive side to the multiplexers 24a to 24c of the selector 24.

At a time t14 that is a delay time delay2 after the time t13, the buffer 26c outputs the output signal Posi data set to the D-type flip-flops 28a to 28d of the holder 28. Accordingly, the D-type flip-flops 28a to 28c of the holder 28 hold data on the positive side. The rest of the processing is substantially the same as that illustrated in FIG. 12.

The processing is described with reference to FIG. 14. FIG. 16 is different from FIG. 13 in that an output signal Nega sel and an output signal Nega data set of the two buffers 26b and 26c in the delay circuit 26n on the negative side are added. That is, a high-level signal H is held in any of the latches 18a to 18e of the negative-side storage 18n at a time t33.

At a time t34 that is the delay time delay1 after the time t33, the buffer 26b of the delay circuit 26n outputs the output signal Nega sel to the direction selector 22. Accordingly, the direction selector 22 changes the selection signal SELECT from 0 to 1 to output the selection signal SELECT that selects a signal on the negative side to the multiplexers 24a to 24c of the selector 24.

At a time t36 that is the delay time delay2 after the time t34, the buffer 26c of the delay circuit 26n outputs the output signal Nega data set to the D-type flip-flops 28a to 28d of the holder 28. Accordingly, the D-type flip-flops 28a to 28c of the holder 28 hold data on the negative side. The rest of the processing is substantially the same as that illustrated in FIG. 13.

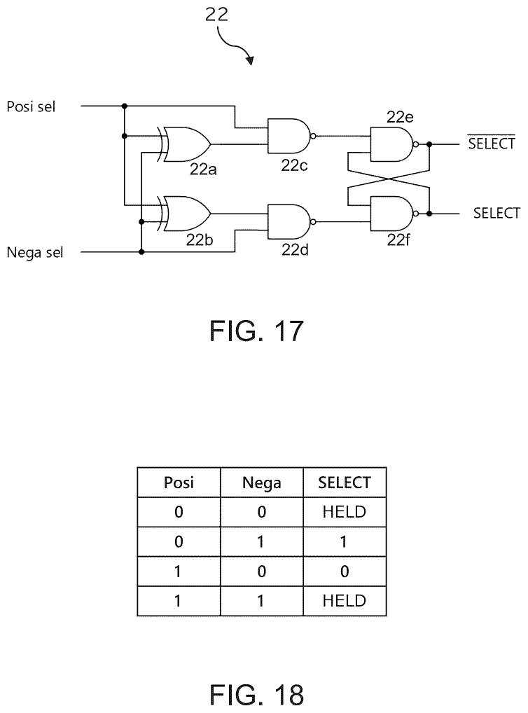

FIG. 17 is a diagram illustrating a logic circuit example of the direction selector 22. The direction selector 22 is constituted of a plurality of exclusive-ORs (XORs) 22a and 22b and a plurality of NANDs 22c to 22f. It is assumed that the output value of the delay circuit 26b (see FIG. 14) on the positive side is the positive signal Posi sel and the output value of the delay circuit 26b (see FIG. 14) on the negative side is the negative signal Nega sel. It is assumed that 1 is output when any of the output values of the positive-side comparator 16p on the positive side is a high level H and 0 is output when all the output values are low levels L. Similarly, it is assumed that 1 is output when any of the output values of the negative-side comparator 16n on the negative side is a high level H and 0 is output when all the output values are low levels L.

In the logic circuit of the direction selector 22, the positive signal Posi sel and the negative signal Nega sel are input to the XOR 22a and the positive signal Posi sel and the negative signal Nega sel are input to the XOR 22b.

An output signal of the XOR 22a and the positive signal Posi sel are input to the NAND 22c. An output signal of the XOR 22b and the negative signal Nega sel are input to the NAND 22d.

An output signal of the NAND 22c and an output signal of the NAND 22f are input to the NAND 22e. An output signal of the NAND 22d and an output signal of the NAND 22e are input to the NAND 22f.

FIG. 18 is a truth table of the positive signal Posi sel and the negative signal Nega sel. In FIG. 18, the positive signal Posi sel is represented by Posi and the negative signal Nega sel is represented by Nega.

When CMT noise is applied, the voltage first transitions to the positive side when the inclination of the application is positive and the voltage then transitions to the negative side when there is a waveform distortion. When the inclination of the application is negative, the voltage transitions in the opposite manner. As is understood from above, a waveform distortion is not erroneously detected when the signal having transitioned first is maintained in preference. Accordingly, in the direction selector 22 according to the present embodiment, first occurred one of transition from L to H on the positive side and transition from L to H on the negative side is held in preference.

As illustrated in FIG. 18, when the signal Posi sel is 1 and the signal Nega sel is 1, the signal SELECT is held. That is, when one of the signal Posi sel and the signal Nega sel becomes 1 being a high-level signal H and subsequently the other thereof becomes 1 being the high-level signal H, the signal SELECT is held because the signals Posi sel and Nega sel are both 1 being the high-level signal H. Therefore, the values of the D-type flip-flops 28a to 28d of the holder 28 are held.

Similarly, when the signal Posi sel is 0 and the signal Nega sel is 0, the signal SELECT is held. That is, in a state where the signal Posi sel and the signal Nega sel are 0 being a low-level signal L, the signal SELECT is held. That is, when CMT noise is not applied, the values of the D-type flip-flops 28a to 28d of the holder 28 are held.

Meanwhile, when the signal Posi sel is 0 being the low-level signal L and the signal Nega sel is 1 being the high-level signal H, the signal SELECT becomes 1 indicating selection on the side of the signal Nega sel.

Meanwhile, when the signal Posi sel is 1 being the high-level signal H and the signal Nega sel is 0 being the low-level signal L, the signal SELECT becomes 0 indicating selection of the signal Posi sel. In this way, when one of the signal Posi sel and the signal Nega sel is 1 and the other thereof is 0, the signal on the positive side or the negative side is selected. Even when the signal Posi sel and the signal Nega sel both thereafter become 1 in a predetermined time, the selection state of the signal selected earlier is held.

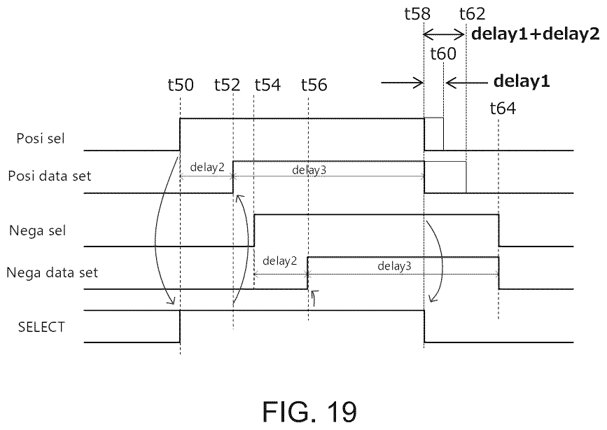

FIG. 19 is an example of a timing chart in a case where CMT noise having a positive inclination is applied and a waveform distortion occurs. At least any of the stored values (L1 to Ln) in the latches of the positive-side storage 18p become a high level H. At a time t50, a delay1 output of the buffer 26b on the positive side transitions from L to H.

Next, at a time t52 that is the delay time delay2 after the time t50, a delay2 output of the buffer 26c on the positive side transitions from a low-level signal L to a high-level signal H. Accordingly, the direction selector 22 outputs a signal direct for selecting data in the positive-side storage 18p to the selector 24 and the holder 28. Subsequently, the holder 28 selects data in the positive-side storage 18p and stores the data therein.

Next, after the delay time delay3, at a time t58, the output signal nCLEAR having passed through the second delay circuit part 30p on the positive side is input to the latches 18a to 18e of the positive-side storage 18p and the latches 18a to 18e of the positive-side storage 18p are unlatched. Accordingly, the signal Posi sel transitions from H to L.

Meanwhile, a waveform distortion occurs, at least any of the stored values (L1 to Ln) in the latches of the negative-side storage 18n becomes a high level H, and a delay1 output of the buffer 26b on the negative side transitions from a low-level signal L to a high-level signal H at a time t54. Accordingly, a high-level signal H is input from the buffers 26b on the positive and negative sides to the direction selector 22. In this way, the high-level signal H is input from the buffer 26b on the negative side with a time lag. In this case, since the signal Posi sel and the signal Nega sel are high-level signals H until the delay time delay3 elapses after data on the positive side is settled, the direction selector 22 outputs a signal indicating hold as the signal SELECT (see FIG. 18). Accordingly, the data on the negative side is invalidated. With this provision of the delay time delay3 as a time for stabilizing influences of CMT noise such as a waveform distortion, erroneous determination can be prevented.

A time t60 is a time the delay time delay1 after the time t58, and a time t62 is a time the delay time delay 2 after the time t60.

At a time t64 that is the delay time delay3 after the time t56, the output signal nCLEAR having passed through the second delay circuit part 30n on the negative side is input to the latches 18a to 18e of the negative-side storage 18n and the latches 18a to 18e of the negative-side storage 18n are unlatched. Accordingly, the signal Nega sel transitions from H to L.

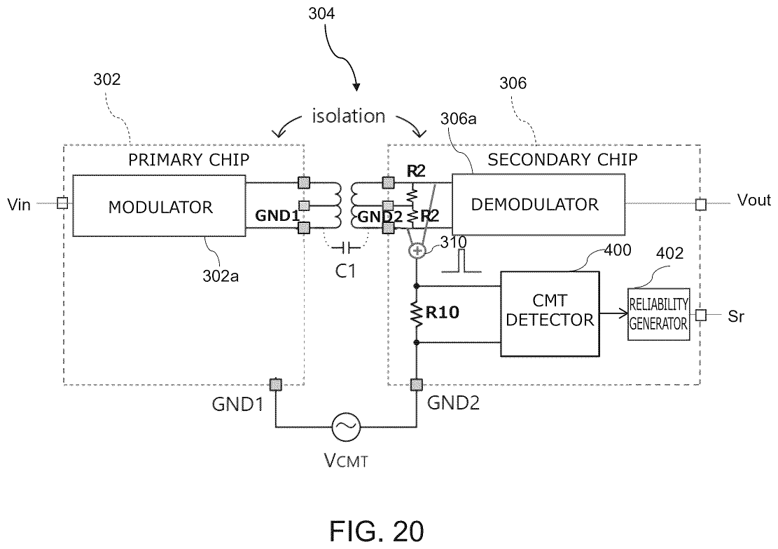

FIG. 20 is a diagram illustrating a configuration example of an isolation amplifier as the signal transmission device 100 according to the first embodiment. The signal transmission device 100 is a device that can use CMT noise as an index of reliability determination of inter-isolation data transmission. The primary chip 302 of the signal transmission device 100 includes a modulator 302a and the secondary chip 306 includes a demodulator 306a, the CMT detector 400, and a reliability generator 402.

The modulator 302a modulates the input signal Vin. For example, the modulator 302a increases the frequency of the input signal Vin to be input. The modulator 302a outputs the modulated input signal Vin to the demodulator 306a through the AC coupler 304.

The demodulator 306a decreases the frequency of a high-frequency signal input through the AC coupler 304. In the present embodiment, increasing the frequency of the input signal Vin is referred to as modulation and decreasing the frequency is referred to as demodulation.

The CMT detector 400 outputs a digital monitor signal having information about a value of the amplitude of CMT noise to the reliability generator 402. The reliability generator 402 generates a reliability signal Sr including information about reliability whose value becomes smaller as the absolute value of the amplitude of CMT noise is larger, and outputs the reliability signal Sr to a processor at the subsequent stage.

The processor at the subsequent stage can apply discarding, retransmission, suspension, or the like of transmitted data using the reliability information based on the CMT noise. The processing according to the reliability information can be freely set depending on systems.

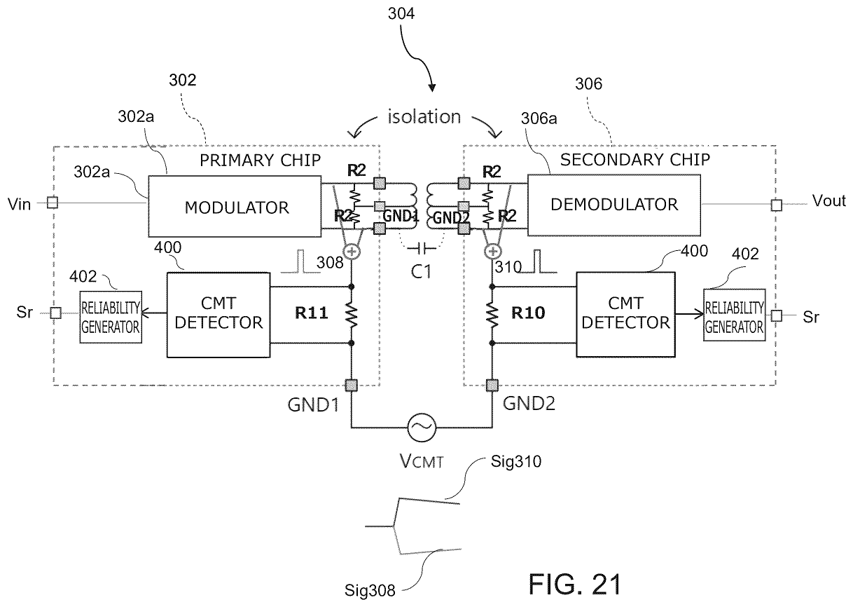

FIG. 21 is a diagram illustrating another configuration example of the isolation amplifier as the signal transmission device 100 according to the first embodiment. The signal transmission device 100 is a device that can use CMT noise as an index of reliability determination of inter-isolation data transmission. This configuration is different from that of the signal transmission device 100 illustrated in FIG. 20 in that the CMT detector 400 and the reliability generator 402 are included also in the primary chip 302 of the signal transmission device 100.

As illustrated in FIG. 21, the CMT detector 400 of the primary chip 302 detects CMT noise Sig308 where a ground GND1 transitions to a negative voltage with respect to a ground GND2, and the CMT detector 400 of the secondary chip 306 detects CMT noise Sig310 where the ground GND1 transitions to a positive voltage with respect to the ground GND2.

In this case, it is unnecessary to determine a pulse on the negative side, and only detection of a pulse on one side enables the CMT noise Sig308 and CMT noise Sig310 to be detected. Accordingly, the CMT detectors 400 can be provided with a larger operation margin, so that the circuit can be simplified and the detection range can be widened.

### Second Embodiment

A gate drive device 102 according to a second embodiment is different from the signal transmission device 100 according to the first embodiment in driving a gate. Differences from the signal transmission device 100 according to the first embodiment are described below.

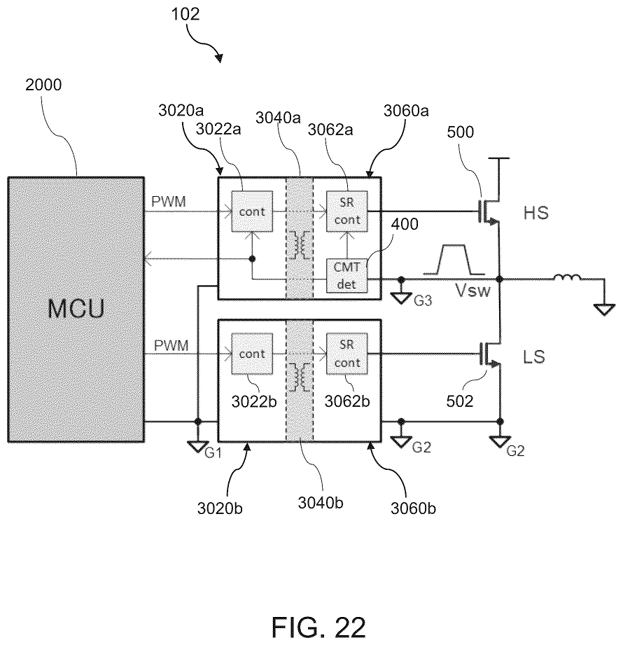

FIG. 22 is a diagram illustrating a configuration example as a gate drive device. As illustrated in FIG. 22, a half-bridge circuit in which a switching element 500 on a power high side (HS) and a switching element 502 on a low side (LS) are connected in series is configured as a control target of the gate drive device 102. A connection point between the switching element 500 and the switching element 502 is connected to a ground terminal (a second reference potential terminal) G3 of a secondary chip 3060a.

The CMT detector 400 generates a signal depending on voltage fluctuations between a gate terminal (a first reference potential terminal) G1 of a primary chip 3020a and the ground terminal G3 of the secondary chip 3060a. CMT noise based on a drain voltage at the connection point between the switching element 500 and the switching element 502 correlates with a time derivative of voltage fluctuations or current fluctuations at the time of switching, and noise is greater when the time derivative is larger. Accordingly, CMT noise and loss of the half-bridge circuit (a power element) are in a trade-off relation.

A controller 2000 controls the time derivative of the voltage fluctuations or the current fluctuations at the time of switching based on the magnitude of the voltage amplitude V_{R} of the CMT noise detected by the CMT detector 400.

FIG. 23 is a diagram illustrating an example of a transient response of a drain voltage. A drain voltage L10 in a case where the slew rate is high and a drain voltage L12 in a case where the slew rate is low are drain voltages of the switching element 500. The horizontal axis represents the time and the vertical axis represents the voltage.

The amplitude voltage indicates an amplitude voltage L20 in a case where the slew rate detected by the CMT detector 400 is high and an amplitude voltage L22 in a case where the slew rate is low. The controller 2000 controls gate drive currents of a drive circuit 3062a (a gate driver) and a drive circuit 3062b (a gate driver) based on the values of the amplitude voltages L20 and L22 detected by the CMT detector 400. That is, the controller 2000 decreases the drive current and increases the driving time when CMT noise is determined to be greater than a specified level on the basis of the value of the amplitude voltage L20. Accordingly, the slew rate of a pulse-width modulation (PWM) signal is decreased.

On the other hand, when CMT noise is determined to be smaller than a specified level on the basis of the value of the amplitude voltage L22, the controller 2000 decreases the drive current and increases the driving time. Accordingly, the slew rate of the PWM signal is increased.

With this feedback control based on the output signal of the CMT detector 400, the slew rate of the drain voltage of the switching element 500 can be controlled.

### Third Embodiment

A gate drive device 102 according to a third embodiment is different from the gate drive device 102 according to the second embodiment in that a gate control circuit 3022a executes time control of power supply of the CMT detector 400. Differences from the gate drive device 102 according to the second embodiment are described below.

FIG. 24 is a block diagram illustrating a configuration on the power high side (HS). This configuration is different from that of the gate drive device 102 according to the second embodiment in further including a power controller 3064a.

The power controller 3064a controls power supply of the CMT detector 400 in accordance with a drive suppression signal (stand by) of the gate control circuit 3022a.

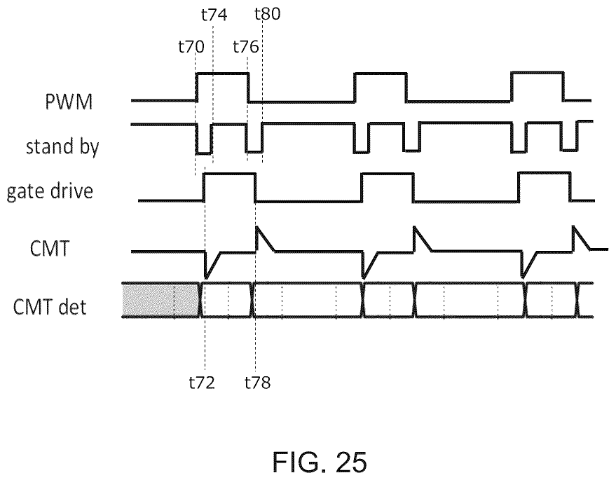

FIG. 25 is a timing chart illustrating a processing example on the power high side (HS). A PWM signal supplied to the power high side (HS), the drive suppression signal (stand by) of the gate control circuit 3022a, a gate control signal (gate drive) output from the drive circuit 3062a, CMT noise (CMT), and a detection timing (CMT det) of the CMT detector 400 are illustrated in this order from the top.

At a time t70, the gate control circuit 3022a brings the drive suppression signal (stand by) to a low level in response to a rising of the PWM signal and outputs the drive suppression signal to the power controller 3064a. The power controller 3064a supplies power to the CMT detector 400 in a predetermined period from the time t70. Accordingly, the CMT detector 400 detects a voltage amplitude of CMT noise occurring in a period based on a time t72 when the gate control signal (gate drive) rises. At a time t74, the drive suppression signal (stand by) is brought to a high level.

Similarly, at a time t76, the gate control circuit 3022a brings the drive suppression signal (stand by) to a low level in response to a falling of the PWM signal and outputs the drive suppression signal to the power controller 3064a. The power controller 3064a supplies power to the CMT detector 400 in a predetermined period from the time t76. Accordingly, the CMT detector 400 detects a voltage amplitude of CMT noise occurring in a period based on a time t78 when the gate control signal (gate drive) falls. At a time t80, the drive suppression signal (stand by) is brought to a high level.

With this supply of power to the CMT detector 400 associated with a period where CMT noise occurs, power consumption of the CMT detector 400 can be suppressed.

While certain embodiments have been described, these embodiments have been presented by way of example only, and are not intended to limit the scope of the inventions. Indeed, the novel embodiments described herein may be embodied in a variety of other forms and various omissions, substitutions, and changes may be made without departing from the spirit of the inventions. The embodiments and their modifications are intended to be included in the scope and the spirit of the invention and also in the scope of the invention and their equivalents described in the claims.

1. A signal transmission device comprising:
a primary circuit;
an AC coupler configured to transmit a transmission signal received from the primary circuit;
a secondary circuit configurated to receive the transmission signal transmitted from the AC coupler; and
a detector configured to output a detection signal related to a noise level at a time of transmission of the transmission signal according to fluctuations of a terminal voltage based on a current flowing in at least either a first reference potential terminal of the primary circuit isolated by the AC coupler or a second reference potential terminal of the secondary circuit, wherein
the detector comprises
one or more first identifiers each configured to compare the terminal voltage with a positive predetermined voltage,
one or more second identifiers each configured to compare the terminal voltage with a negative predetermined voltage,
a first encoder configured to perform encoding of information related to a slew rate of the terminal voltage on a basis of a comparison result of the first identifiers, and
a second encoder configured to perform encoding of information related to a slew rate of the terminal voltage on a basis of a comparison result of the second identifiers.

2. The device of claim 1, wherein
in the detector,
at least either the first encoder or the second encoder starts an operation of encoding a polarity of a slew rate of the terminal voltage and a magnitude of the slew rate in response to occurrence of a state change of at least any of the first identifiers and the second identifiers.

3. The device of claim 2, wherein
the detector further comprises
a direction selector configured to output a selection signal to select either the first encoder or the second encoder associated with either the first identifiers or the second identifiers having performed a comparison, and
a selector configured to select either the first identifiers or the second identifiers in accordance with the selection signal.

4. The device of claim 3, wherein the direction selector selects either the first identifiers or the second identifiers having first performed comparison processing.

5. The device of claim 3, wherein the direction selector holds an output of the selection signal for a predetermined period when outputting the selection signal.

6. The device of claim 1, wherein
the first encoder performs encoding of information indicating a magnitude of a slew rate of a positive polarity, and
the second encoder performs encoding of information indicating a magnitude of a slew rate of a negative polarity.

7. The device of claim 1, wherein the detector outputs a slew rate signal having information related to the slew rate as the detection signal on a basis of comparison results of the first identifiers and the second identifiers.

8. The device of claim 1, wherein the AC coupler is a transformer configured to cause inductors having a potential of the first reference potential terminal and a potential of the second reference potential terminal as references to be close to each other and to transmit a signal from the primary circuit to the secondary circuit or from the secondary circuit to the primary circuit.

9. A gate drive device comprising:
a primary circuit configured to modulate a gate signal to transmit the gate signal;
an AC coupler configured to transmit the signal received from the primary circuit;
a secondary circuit configurated to demodulate the gate signal transmitted from the AC coupler and supply the gate signal to a gate of a switching element; and
a detector configured to output a detection signal related to a noise level at a time of transmission of a transmission signal according to fluctuations of a terminal voltage based on a current flowing in at least either a first reference potential terminal of the primary circuit isolated by the AC coupler or a second reference potential terminal of the secondary circuit, wherein
the secondary circuit controls a slew rate of a gate voltage of the switching element driven by the gate signal in accordance with the detection signal.

10. The device of claim 9, wherein
the gate signal is a pulse-width modulation signal, and
the device further comprises a controller configured to control a supply amount of power supplied to the detector on a basis of at least any timing of risings and fallings of a pulse.

11. The device of claim 9, wherein
the detector comprises
one or more first identifiers each configured to compare the terminal voltage with a positive predetermined voltage,
one or more second identifiers each configured to compare the terminal voltage with a negative predetermined voltage,
a first encoder configured to perform encoding of information related to a slew rate of the terminal voltage on a basis of a comparison result of the first identifiers, and
a second encoder configured to perform encoding of information related to a slew rate of the terminal voltage on a basis of a comparison result of the second identifiers.

12. The device of claim 11, wherein
in the detector,
at least either the first encoder or the second encoder starts an operation of encoding a polarity of a slew rate of the terminal voltage and a magnitude of the slew rate in response to occurrence of a state change of at least any of the first identifiers and the second identifiers.

13. The device of claim 12, wherein
the detector further comprises
a direction selector configured to output a selection signal to select either the first encoder or the second encoder associated with either the first identifiers or the second identifiers having performed a comparison, and
a selector configured to select either the first identifiers or the second identifiers in accordance with the selection signal.

14. The device of claim 13, wherein the direction selector selects either the first identifiers or the second identifiers having first performed comparison processing.

15. The device of claim 13, wherein the direction selector holds an output of the selection signal for a predetermined period when outputting the selection signal.

16. The device of claim 11, wherein
the first encoder performs encoding of information indicating a magnitude of a slew rate of a positive polarity, and
the second encoder performs encoding of information indicating a magnitude of a slew rate of a negative polarity.

17. The device of claim 11, wherein the detector outputs a slew rate signal having information related to the slew rate as the detection signal on a basis of comparison results of the first identifiers and the second identifiers.

18. The device of claim 9, wherein the AC coupler is a transformer configured to cause inductors having a potential of the first reference potential terminal and a potential of the second reference potential terminal as references to be close to each other and to transmit a signal from the primary circuit to the secondary circuit or from the secondary circuit to the primary circuit.
